(19) United States
(12) Patent Application Publication
(10) Pub. No.: US 2021/0358823 A1
(43) Pub. Date: Nov. 18, 2021

(54) SEMICONDUCTOR PACKAGE STRUCTURE AND METHOD FOR MANUFACTURING THE SAME

(71) Applicant: Advanced Semiconductor Engineering, Inc., Kaohsiung (TW)

(72) Inventors: Chi Sheng TSENG, Kaohsiung (TW); Lu-Ming LAI, Kaohsiung (TW); Yu-Che HUANG, Kaohsiung (TW); Shih-Chieh TANG, Kaohsiung (TW); Yu-Min PENG, Kaohsiung (TW); Hui-Chung LIU, Kaohsiung (TW)

(73) Assignee: Advanced Semiconductor Engineering, Inc., Kaohsiung (TW)

(21) Appl. No.: 16/877,197

(22) Filed: May 18, 2020

(51) Int. Cl. H01L 23/31; H01L 21/56

(52) U.S. Cl. CPC H01L 23/3114; H01L 21/56; H01L 23/3135

(57) ABSTRACT

A semiconductor package structure and a method for manufacturing a semiconductor package structure are provided. The semiconductor package structure includes a semiconductor package structure includes a semiconductor die and a light absorbing layer. The semiconductor die has a first surface, a second surface and a third surface. An active layer of the semiconductor die is adjacent to the first surface. The second surface is opposite to the first surface. The third surface extends from the first surface to the second surface. The light absorbing layer covers the second surface and the third surface of the semiconductor die. The semiconductor die has a thickness defined from the first surface to the second surface, and the thickness of the semiconductor die is less than or equal to about 300 micrometers (μm).

### BACKGROUND

### 1. Field of the Disclosure

The present disclosure relates to a semiconductor package structure, and in particularly to a semiconductor package structure with a light absorbing layer.

### 2. Description of the Related Art

Conventionally, a semiconductor package structure has a semiconductor die with a sufficient thickness to block light generating noise. As the size of the semiconductor package structures is decreased, a thinner semiconductor die is needed. However, when the thickness of the semiconductor die is too thin, light will pass through the semiconductor die and arrive at an active layer causing a noise, influencing the performance of the semiconductor package structure. Therefore, a new semiconductor package structure is required to solve above problems.

### SUMMARY

In some embodiments, a semiconductor package structure includes a semiconductor die and a light absorbing layer. The semiconductor die has a first surface, a second surface and a third surface. An active layer of the semiconductor die is adjacent to the first surface. The second surface is opposite to the first surface. The third surface extends from the first surface to the second surface. The light absorbing layer covers the second surface and the third surface of the semiconductor die. The semiconductor die has a thickness defined from the first surface to the second surface, and the thickness of the semiconductor die is less than or equal to about 300 micrometers (μm).

In some embodiments, a method for manufacturing a semiconductor package structure includes: providing a semiconductor die, the semiconductor die comprising a first surface, a second surface and a third surface, wherein the second surface is opposite to the first surface, and the third surface extends from the first surface to the second surface; and forming a light absorbing layer to cover the second surface and the third surface of the semiconductor die, wherein the light absorbing layer includes a first portion having a first thickness and a second portion having a second thickness less than the first thickness.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an example of a semiconductor package structure according to some embodiments of the present disclosure.

FIG. 1A illustrates a cross-sectional view of an example of a semiconductor package structure according to some embodiments of the present disclosure.

FIG. 2 illustrates a cross-sectional view of an example of a semiconductor package structure according to some embodiments of the present disclosure.

FIG. 3 illustrates a cross-sectional view of an example of a semiconductor package structure according to some embodiments of the present disclosure.

FIG. 4 illustrates a cross-sectional view of an example of a semiconductor package structure according to some embodiments of the present disclosure.

FIG. 5 illustrates a cross-sectional view of an example of a semiconductor package structure according to some embodiments of the present disclosure.

FIG. 6 illustrates a cross-sectional view of an example of a semiconductor package structure according to some embodiments of the present disclosure.

FIG. 7 illustrates a cross-sectional view of an example of a semiconductor package structure according to some embodiments of the present disclosure.

FIG. 8 illustrates a cross-sectional view of an example of a semiconductor package structure according to some embodiments of the present disclosure.

FIG. 9 illustrates a cross-sectional view of an example of a semiconductor package structure according to some embodiments of the present disclosure.

FIG. 10 illustrates a cross-sectional view of an example of a semiconductor package structure according to some embodiments of the present disclosure.

FIG. 11 illustrates a cross-sectional view of an example of a semiconductor package structure according to some embodiments of the present disclosure.

FIG. 12 illustrates a cross-sectional view of an example of a semiconductor package structure according to some embodiments of the present disclosure.

FIG. 13A illustrates a cross-sectional view of an example of a semiconductor package structure according to some embodiments of the present disclosure.

FIG. 13B illustrates a cross-sectional view of a comparative semiconductor device according to some embodiments of the present disclosure.

FIG. 14A, FIG. 14B, FIG. 14C, FIG. 14D, FIG. 14E, FIG. 14F. and FIG. 14G illustrate various stages of a method for manufacturing a semiconductor device in accordance with some embodiments of the present disclosure.

FIG. 15A, FIG. 15B and FIG. 15C illustrate various stages of a method for manufacturing a semiconductor package structure in accordance with some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

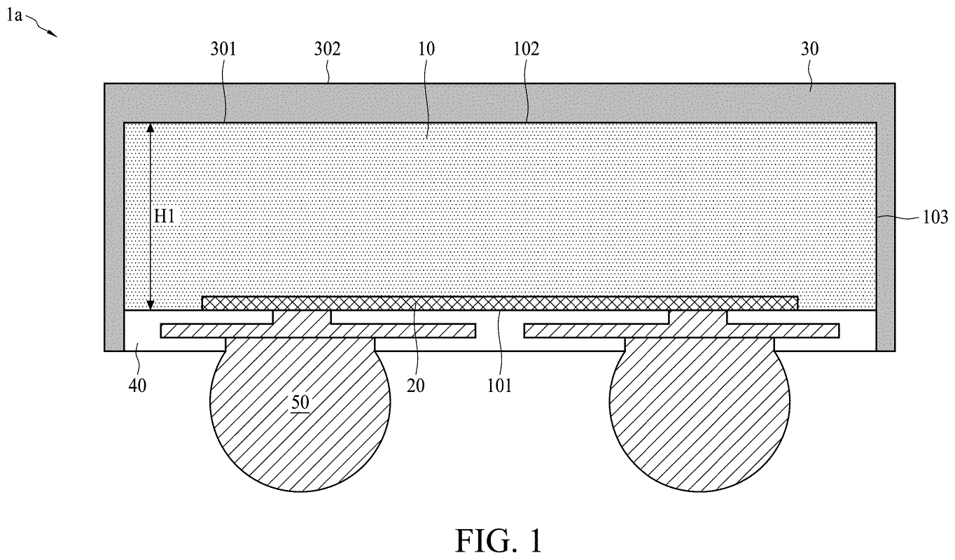

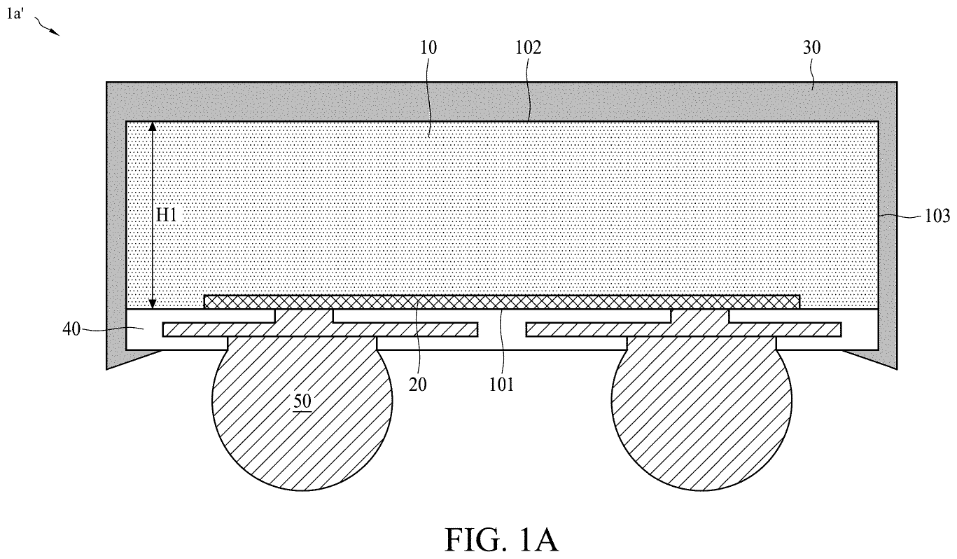

FIG. 1 illustrates a cross-sectional view of an example of a semiconductor package structure 1a according to some embodiments of the present disclosure. In some embodiments, the semiconductor package structure 1a includes a semiconductor die 10 and a light absorbing layer 30.

The semiconductor die 10 may include a silicon substrate or other suitable substrate(s). The semiconductor die 10 may have a surface 101, a surface 102 opposite to the surface 101, and a surface 103 extending from the surface 101 to the surface 102. The surface 101 may also be referred to as an active surface or the first surface. The surface 102 may also be referred to as a backside surface or the second surface. The surface 103 may also be referred to as a side surface or the third surface. In some embodiments, the semiconductor die 10 has a thickness H1, defined from the surface 101 to the surface 102, greater than 0, and less than or equal to about 300 micrometers (μm).

The semiconductor die 10 may include an active layer 20. The active layer 20 may be disposed on the surface 101 of the semiconductor die 10. In some embodiments, the active layer 20 may be embedded adjacent to the surface 101 of the semiconductor die 10. In some embodiments, a portion of the active layer 20 may be disposed on the surface 101 of the semiconductor die 10, and another portion is embedded in the semiconductor die 10, and the present disclosure is not intended to be limited thereto. In some embodiments, the active layer 20 may include optical sensitive element(s). The active layer 20 may include one or more integrated circuits (ICs). For example, the active layer 20 may include a combination of diodes, transistors or other suitable elements.

The light absorbing layer 30 may cover the surfaces 102 and 103 of the semiconductor die 10. That is, the light absorbing layer 30 may surround all edges of the surface 102 from a top view. The light absorbing layer 30 is configured to prevent light from being incident to the active layer 20 through the surface 102 and/or 103. The light absorbing layer 30 may absorb light, especially for the light with wavelength of about 390 nm to about 1000 nm. For example, when the light absorbing layer 30 has a thickness of about 2 μm, 0.1% or less light with wavelength of 390 nm to 1000 nm may pass through the light absorbing layer 30. In some embodiments, when the semiconductor die 10 has a thickness of about 300 μm and the light absorbing layer 30 has a thickness of about 2 μm, the incident light from the surface 302 may be absorbed by the light absorbing layer 30 and semiconductor die 10 and the remained light to the active layer 20 may be decade to 0.01% or less.

In some embodiments, the material of the light absorbing layer 30 may include polymer, such as acrylic resin, polyvinyl alcohol, and polyimide. In some embodiments, the light absorbing layer 30 may include carbon black. In some embodiments, the light absorbing layer 30 does not include a photoactive agent. In some embodiments, the light absorbing layer 30 is free from optically-cured material.

The light absorbing layer 30 may have an inner surface 301 facing the semiconductor die 10 and an outer surface 302 opposite to the inner surface 301. In this disclosure, the thickness of the light absorbing layer 30 may be measured along the normal direction of the surface 102 or 103. In this disclosure, the light absorbing layer 30 may have different thicknesses on different location. For example, the light absorbing layer 30 may have a thicker thickness on the surface 102 and a thinner thickness on the surface 103. However, the present disclosure is not intended to be limited thereto. In some embodiments, the light absorbing layer 30 may have a thickness ranging from about 1.5 μm to 5 μm. In some embodiments, the light absorbing layer 30 may have a thickness ranging from about 5 μm to 10 μm. In some embodiments, the light absorbing layer 30 may have a thickness ranging from about 10 μm to 30 μm.

The semiconductor package structure 1a may include a passivation layer 40. The passivation layer 40 may cover the surface 101 of the semiconductor die 10. The passivation layer 40 may cover the active layer 20. The passivation layer 40 may be configured to protect the conductive elements, active layer 20 and/or other elements in the semiconductor die 10 from being damaged or contaminated. The passivation layer 40 may include nitride, oxide, oxynitride, resin or other suitable materials.

The semiconductor package structure 1a may include terminals 50. The terminal 50 may be configured to electrically connect the semiconductor package structure 1a and other element(s), such as a printed circuited board (PCB). In some embodiments, the terminal 50 is a solder ball (e.g., Sn ball). The active layer 20 may be electrically connected to the terminal 50 through conductive wires formed in the semiconductor die 10 or in the passivation layer 40.

In some embodiments, the semiconductor package structure 1a includes the light absorbing layer 30 that can serve as a light-shielding layer, which reduces the noise signal and assists in manufacturing the semiconductor package structure 1a with a smaller size in comparison with conventional semiconductor package structure. For example, a comparative semiconductor package structure may use a metal layer serving as a light-shielding layer. Because light may be reflected from the metal, metal shielding layer may cause light to be reflected and then incident to other elements or devices that are sensitive to light, which may adversely impact other elements or devices. Another comparative semiconductor package structure may use a molding compound serving as a light-shielding layer to prevent light from being reflected. However, considering the limitation of molding process and the tolerance of saw singulation, the thickness of molding compound is more than 50 Further, the molding compound should have a thickness more than 150 μm to ensure that most of light can be absorbed by the molding compound, which increases the size of the semiconductor package structure.

FIG. 1A illustrates a cross-sectional view of an example of a semiconductor package structure 1a′ according to some embodiments of the present disclosure. In some embodiments, the passivation layer 40 may fully cover the surface 101 of the semiconductor die 10, and the light absorbing layer 30 may further cover a portion of the passivation layer 40. In some embodiments, a portion of the light absorbing layer 30 may cover the passivation layer 40 adjacent to the surface 103. The portion of the light absorbing layer 30 may have a substantially uniform thickness, or the thickness of the portion of the light absorbing layer 30 may gradually decrease or increase from the surface 103 toward the surface 101.

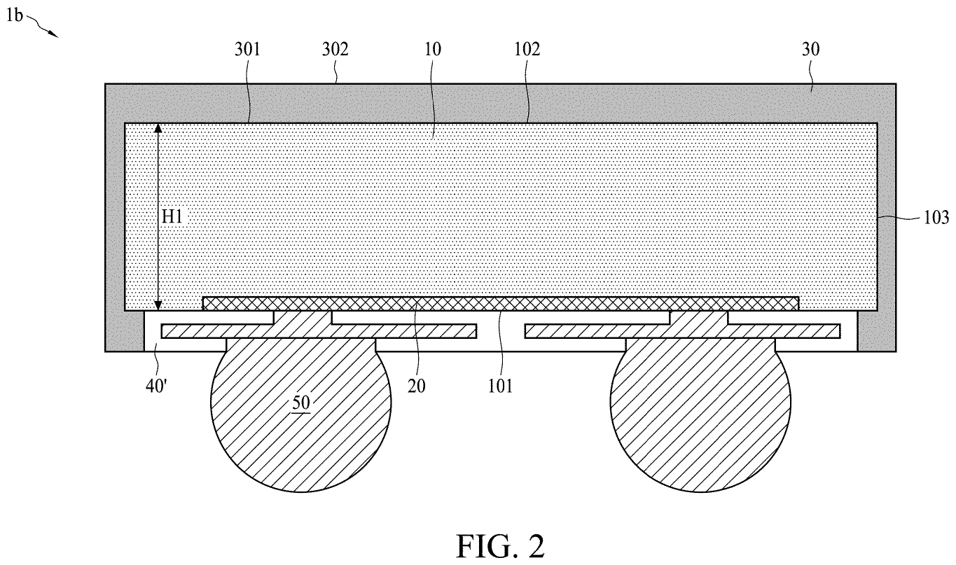

FIG. 2 illustrates a cross-sectional view of an example of a semiconductor package structure 1b according to some embodiments of the present disclosure. The semiconductor package structure 1b of FIG. 2 has a structure similar to that of the semiconductor package structure 1a of FIG. 1 with differences that the semiconductor package structure 1b has a passivation layer 40′. The passivation layer 40′ may exposes a portion of the surface 101 of the semiconductor die 10. That is, the surface 101 is not completely covered by the passivation layer 40′. In some embodiments, the light absorbing layer 30 may further cover a portion of the surface 101 of the semiconductor die 10. In other embodiments, the passivation layer 40′ may partially cover the surface 101 of the semiconductor die 10, and the light absorbing layer 30 may further cover a portion of the surface 101 of the semiconductor die 10 exposed from the passivation layer 40′.

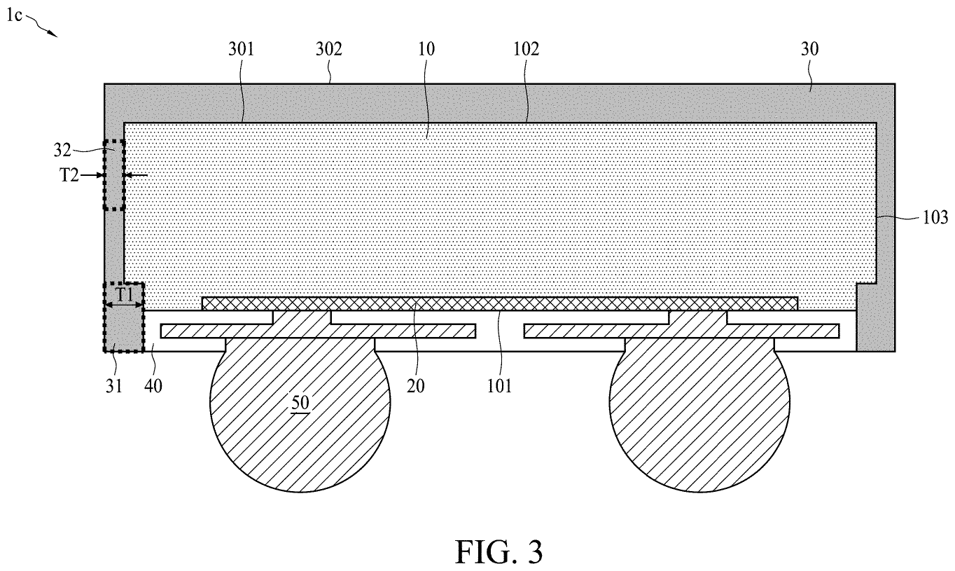

FIG. 3 illustrates a cross-sectional view of an example of a semiconductor package structure 1c according to some embodiments of the present disclosure. The semiconductor package structure 1c of FIG. 3 has a structure similar to that of the semiconductor package structure 1a of FIG. 1 with differences that the light absorbing layer 30 may have a portion 31 and a portion 32 with different thicknesses.

In some embodiments, a portion of the semiconductor die 10 may be cut or removed. In some embodiments, the corner of the surface 103 and the surface 101 of the semiconductor die 10 may be cut or removed such that the semiconductor die 10 may have a step profile at the corner of the surface 101 and the surface 103. In this disclosure, the corner may mean that an area that two surfaces meet. From a bottom view, when the corner of the surface 103 and the surface 101 of the semiconductor die 10 is cut or removed, the semiconductor die 10 may have a ring-shaped recess in the peripheral region of the surface 101 and a protruding portion in the central region of the surface 101. The recess may correspond to the corner of the cross-sectional view, such as FIG. 3.

When a portion of the semiconductor die 10 is removed, it assists in forming the light absorbing layer 30 with thicker thickness corresponding to the removed portion. In some embodiments, the portion 31 is positioned at corresponding to the removed portion of the semiconductor die 10. In some embodiments, the portion 31 abuts the surface 101. In some embodiments, the portion 31 may be disposed on the surface 103. The portion 32 is positioned at corresponding to a non-removed portion of the semiconductor die 10. In some embodiments, the inner surface 301 of the portion 31 and the inner surface 301 of the portion 32 form a step profile at the corner of the surface 101 and the surface 103 of the semiconductor die 10.

The portion 31 has a thickness T1. The portion 32 has a thickness T2. In some embodiments, the thickness T1 is greater than the thickness T2. The portion 31 may have a thicker thickness and abut the surface 101. In some embodiments, the portion 31 may have an elevation higher than an elevation of the active layer 20. That is, the portion 31 covers the active layer 20 along a horizontal direction. That is, the portion 31 may completely cover the active layer 20 along a horizontal direction. In this embodiment, even light is incident from a side near the active layer 20, most of light is absorbed by the portion 31 and thus reduces signal noise generated by undesired light.

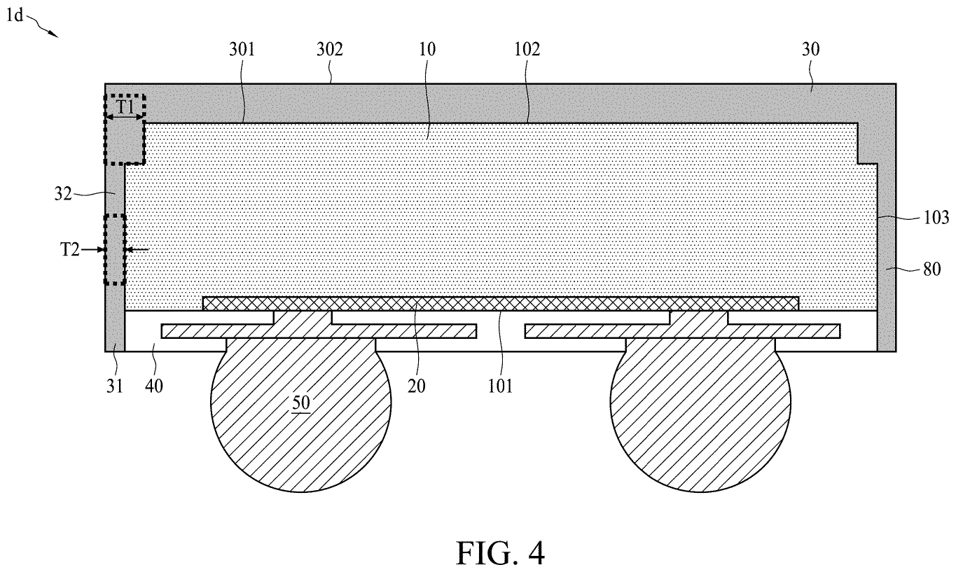

FIG. 4 illustrates a cross-sectional view of an example of a semiconductor package structure 1d according to some embodiments of the present disclosure. The semiconductor package structure 1d of FIG. 4 has a structure similar to that of the semiconductor package structure 1c of FIG. 3 with differences of the position of the portion 31.

In some embodiments, the corner of the surface 103 and the surface 102 is cut or removed such that the semiconductor die 10 may have a step profile at the corner of the surface 102 and the surface 103. From a top view, the semiconductor die 10 may have a ring-shaped recess in the peripheral region of the surface 102 and a protruding portion in the central region of the surface 102. The recess may correspond to the corner of the cross-sectional view, such as FIG. 3.

The portion 31 is positioned at corresponding to the removed portion of the semiconductor die 10. In this embodiment, the portion 31 may abut the surface 102. Therefore, the light absorbing layer 30 has a thicker thickness corresponding to the corner defined by the surface 102 and the surface 103. In some embodiments, the inner surface 301 of the portion 31 and the inner surface 301 of the portion 32 form a step profile at the corner of the surface 102 and the surface 103 of the semiconductor die 10.

Because the light absorbing layer 30 is formed by a spray coating process, and thus may have a sagging phenomenon, which causes the light absorbing layer 30 to have a thinner thickness at the corner of the semiconductor die 10. In this embodiment, the corner of the semiconductor die 10 is removed, assisting in forming a thicker light absorbing layer 30 to compromise the sagging phenomenon.

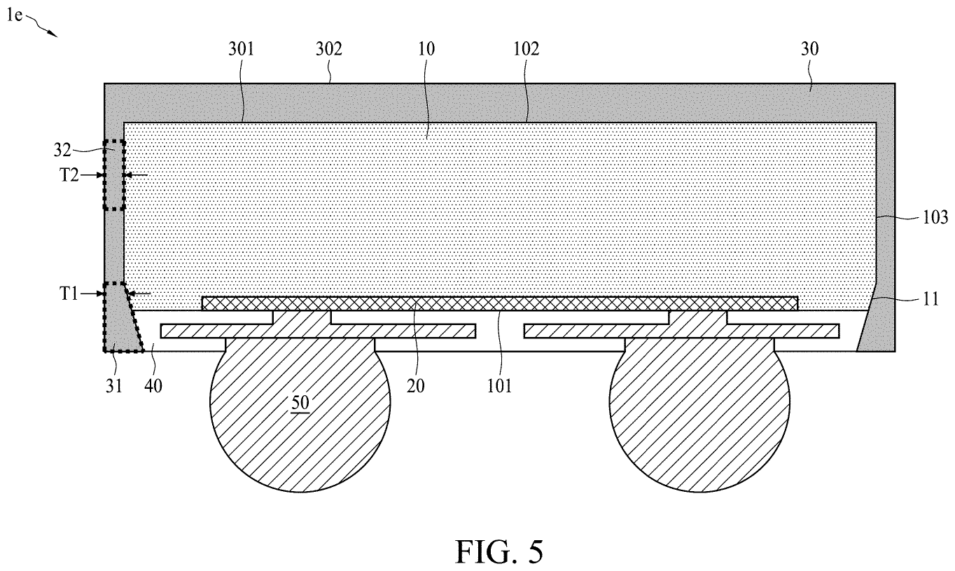

FIG. 5 illustrates a cross-sectional view of an example of a semiconductor package 1e structure according to some embodiments of the present disclosure. The semiconductor package structure 1e of FIG. 5 has a structure similar to that of the semiconductor package structure 1c of FIG. 3 with differences of the profile of the portion 31.

In some embodiments, the corner of the surface 101 and the surface 103 of the semiconductor 10 may be cut or removed with a bevel cut such that the semiconductor die 10 may have a tapered portion abutting the surface 101. In some embodiments, a portion of the passivation layer 40 is removed such that the semiconductor die 10 and the passivation layer 40 may have a coplanar surface. In some embodiments, the tapered portion of the semiconductor die 10 may taper along a direction from surface 102 toward the surface 101.

In some embodiments, the portion 31 may include a tapered portion positioned on the tapered portion of the semiconductor die 10. In some embodiments, the portion 31 may taper along a direction from the surface 101 toward the surface 102. In some embodiments, the light absorbing layer 30 may have a curved surface at the corner defined by the surface 101 and the surface 103 of the semiconductor die 10. That is, the inner surface 301 of the light absorbing layer 30 is curved corresponding to the corner of the surface 101 and the surface 103. In some embodiments, the curved surface of the light absorbing layer 30 is concaved with respect to the semiconductor die 10. In some embodiments, the inner surface 301 of the portion 31 is tapered with respect to the outer surface 302 of the portion 31. In some embodiments, the portion 32 may include a non-tapered portion corresponding to a non-removed portion of the semiconductor die 10. The inner surface 301 of the portion 32 is substantially parallel to the outer surface 302 of the portion 32.

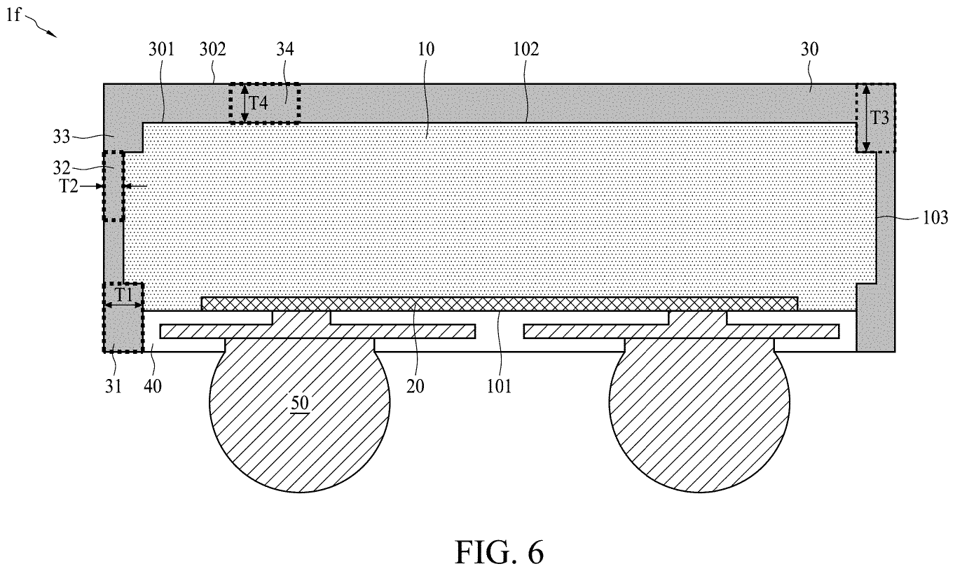

FIG. 6 illustrates a cross-sectional view of an example of a semiconductor package structure if according to some embodiments of the present disclosure. The semiconductor package structure if of FIG. 6 has a structure similar to that of the semiconductor package structure 1c of FIG. 3 with differences that the light absorbing layer 30 may have two thicker portions, such as the portions 31 and 33, abutting the surface 101 and surface 102, respectively.

In some embodiments, the light absorbing layer 30 may have a portion 33 and a portion 34. The portion 33 is positioned on the removed portion of the semiconductor die 10. The portion 33 may abut the surface 102. The portion 34 is positioned on the non-removed portion of the semiconductor die 10. The portion 33 has a thickness T3. The portion 34 has a thickness T4. In some embodiments, the thickness T3 is greater than the thickness T4. In some embodiments, the thickness T4 is greater than the thickness T2. In this embodiment, the light absorbing layer 30 may have thicker portions corresponding to the corner of the surface 101 and the surface 103 and to the corner of the surface 102 and the surface 103, respectively.

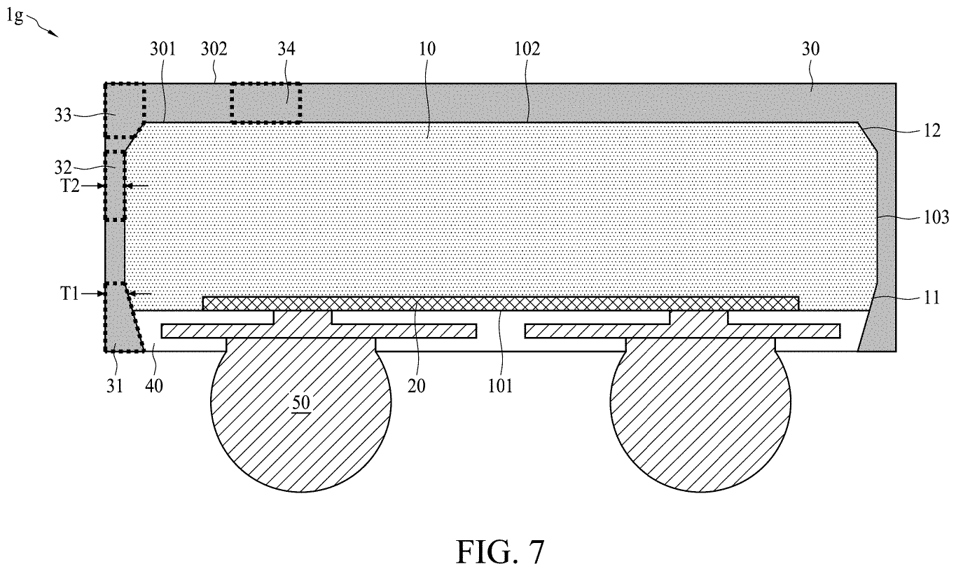

FIG. 7 illustrates a cross-sectional view of an example of a semiconductor package structure 1g according to some embodiments of the present disclosure. The semiconductor package structure 1g of FIG. 7 has a structure similar to that of the semiconductor package structure 1e of FIG. 5 with differences that the semiconductor package structure 1g further includes a portion 33 and a portion 34.

In some embodiments, the corner of the surface 102 and the surface 103 is removed with a bevel cut such that the semiconductor die 10 may have a tapered portion abutting the surface 102. In some embodiments, the tapered portion of the semiconductor die 10 may taper along a direction from surface 101 toward the surface 102.

In some embodiments, the portion 33 may include a tapered portion on the tapered portion of the semiconductor die 10. In some embodiments, the portion 33 may taper along a direction from the surface 102 toward the surface 101. In some embodiments, the light absorbing layer 30 may have a curved surface at the corner of the surface 102 and the surface 103 of the semiconductor die 10. That is, the inner surface 301 of the light absorbing layer 30 is curved at the corner of the surface 102 and the surface 103. In some embodiments, the portion 34 may include a non-tapered portion corresponding to a non-removed portion of the semiconductor die 10. The inner surface 301 of the portion 34 is substantially parallel to the outer surface 302 of the portion 34.

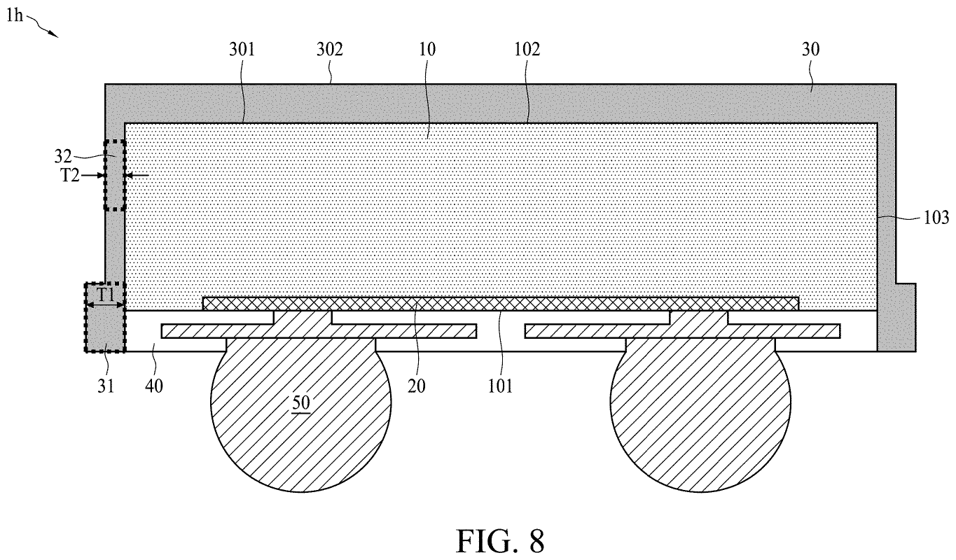

FIG. 8 illustrates a cross-sectional view of an example of a semiconductor package structure 1h according to some embodiments of the present disclosure. The semiconductor package structure 1h of FIG. 8 has a structure similar to that of the semiconductor package structure 1c of FIG. 3 with differences that the corner of the semiconductor die 10 of the semiconductor package structure 1h is not removed. In some embodiments, the outer surface 302 of the portion 32 and the outer surface 302 of the portion 31 form a step profile at the corner of the surface 101 and the surface 103.

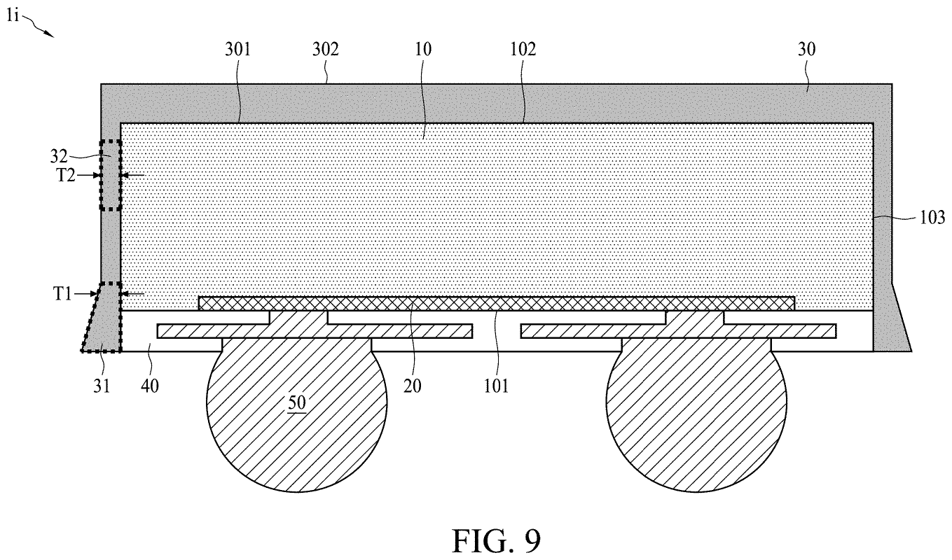

FIG. 9 illustrates a cross-sectional view of an example of a semiconductor package structure 1i according to some embodiments of the present disclosure. The semiconductor package structure 1i of FIG. 9 has a structure similar to that of the semiconductor package structure 1e of FIG. 5 with differences that the corner of the semiconductor die 10 of the semiconductor package structure 1i is not removed. In this embodiment, the portion 31 may include a tapered portion at the corner of the surface 101 and the surface 102. In some embodiments, the portion 31 may taper along a direction from the surface 101 toward the surface 102. In some embodiments, the outer surface 302 of the portion 31 is tapered with respect to the inner surface 301.

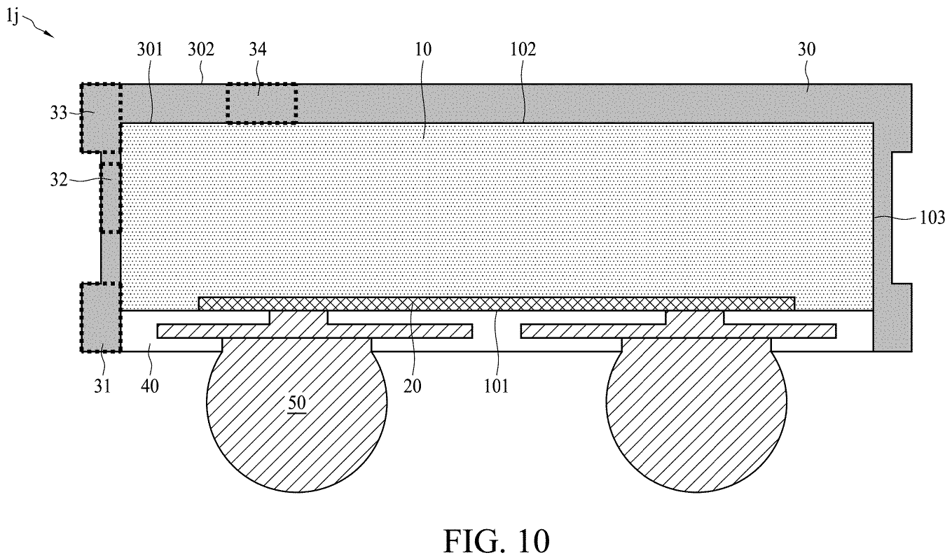

FIG. 10 illustrates a cross-sectional view of an example of a semiconductor package structure 1j according to some embodiments of the present disclosure. The semiconductor package structure 1j of FIG. 10 has a structure similar to that of the semiconductor package structure if of FIG. 6 with differences that the corner of the semiconductor die 10 of the semiconductor package structure 1i is not removed. In some embodiments, the outer surface 302 of the portion 33 and the outer surface 302 of the portion 32 form a step profile at the corner of the surface 102 and the surface 103.

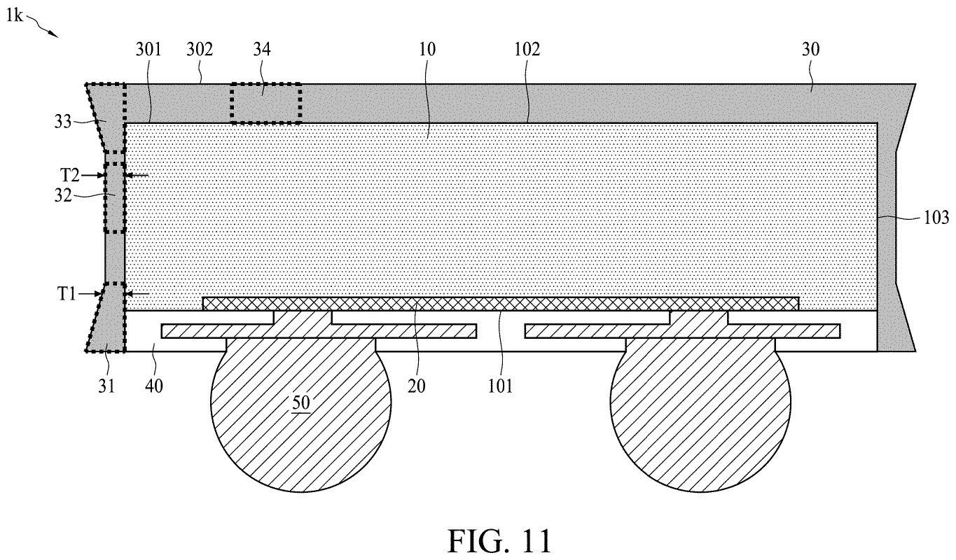

FIG. 11 illustrates a cross-sectional view of an example of a semiconductor package structure 1k according to some embodiments of the present disclosure. The semiconductor package structure 1k of FIG. 11 has a structure similar to that of the semiconductor package structure 1g of FIG. 7 with differences that the corner of the semiconductor die 10 of the semiconductor package structure 1k is not removed. In some embodiments, the portion 33 may taper along a direction from the surface 102 toward the surface 101. In some embodiments, the outer surface 302 of the portion 33 is tapered with respect to the inner surface 301.

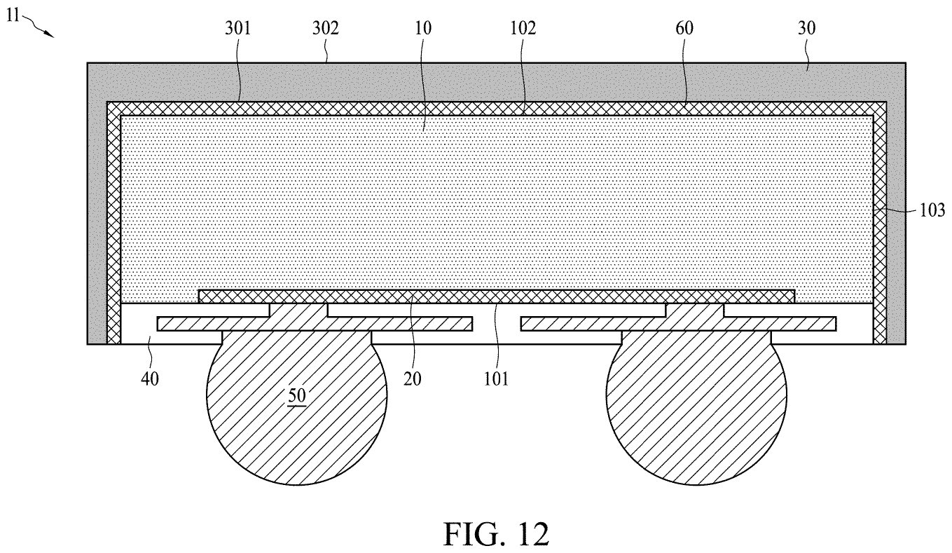

FIG. 12 illustrates a cross-sectional view of an example of a semiconductor package structure 1l according to some embodiments of the present disclosure. The semiconductor package structure 1l of FIG. 12 has a structure similar to that of the semiconductor package structure 1a of FIG. 1 with differences that the semiconductor package structure 1l includes a shielding layer 60.

The shielding layer 60 may cover the surface 102 and the surface 103 of the semiconductor die 10. The light absorbing layer 30 may cover the shielding layer 60. In some embodiments, the shielding layer 60 is disposed between the semiconductor die 10 and the light absorbing layer 30. The material of the shielding layer 60 may include metal, metal alloy or other suitable materials. In some embodiments, the conductivity of the light absorbing layer 30 is less than that of the shielding layer 60. The shielding layer 60 may be configured to serve as electromagnetic shielding (EMI) layer. In this embodiment, the shielding layer 60 is covered by the light absorbing layer 30. Therefore, the incident light may be absorbed by the light absorbing layer 30 such that other elements (not shown) may be freed from negative impact of reflected light.

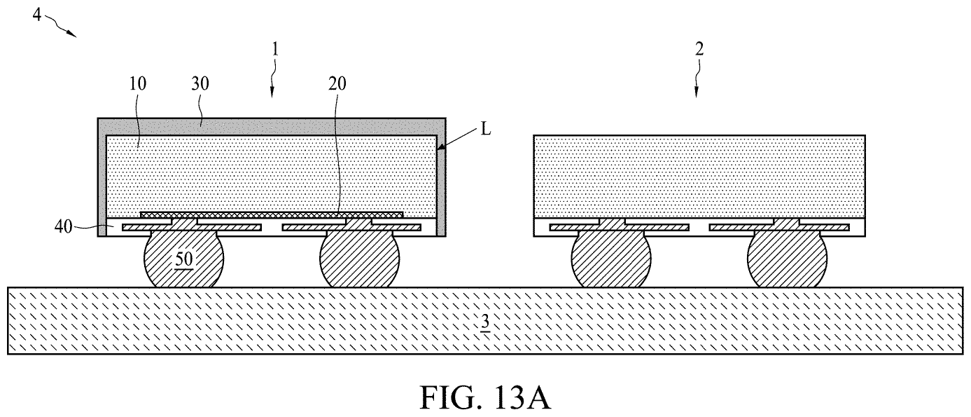

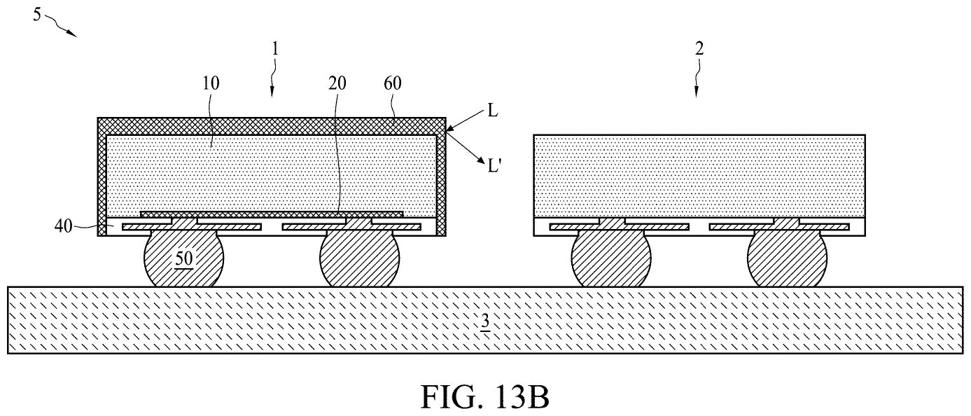

FIG. 13A illustrates a cross-sectional view of an example of a semiconductor device 4 according to some embodiments of the present disclosure. The semiconductor device 4 may include a semiconductor package structure 1 and at least one element 2 attached on a substrate 3.

The semiconductor package structure 1 may be one of the semiconductor package structures 1a-1l. The element 2 may include optical element or non-optical element, which may include multiple ICs. The substrate 3 may include a PCB or other suitable substrate. In some embodiments, the element 2 is an optical sensitive element. In this embodiment, light L, incident to the semiconductor package structure 1, is absorbed by the light absorbing layer 30 such that the element 2 may be free from negative impact of reflected light from light L.

FIG. 13B illustrates a cross-sectional view of a comparative semiconductor device 5 according to some embodiments of the present disclosure. The semiconductor device 5 does not include a light absorbing layer. The semiconductor device 5 includes a shielding layer 60. As shown in FIG. 13B, when light L is incident to the semiconductor die 10, a reflected light L′ is reflected from the shielding layer 60. As a result, the element 2 may be impacted by the reflected light L′.

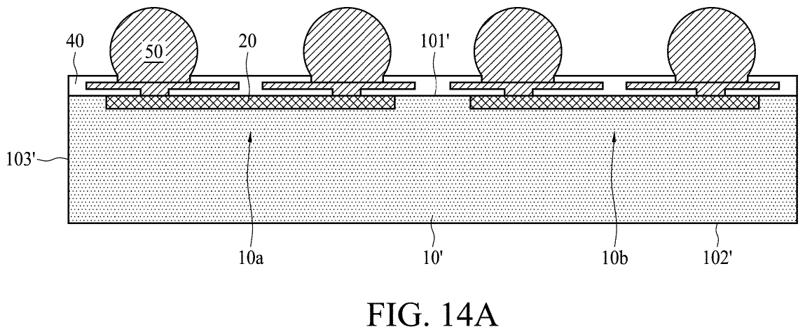

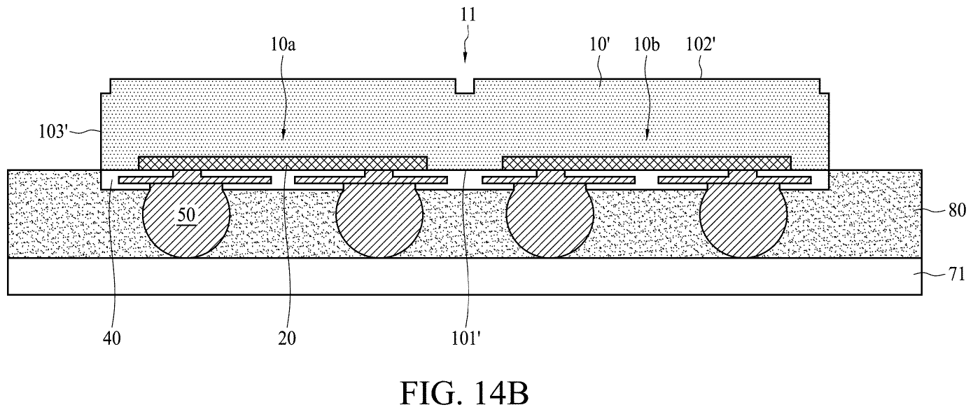

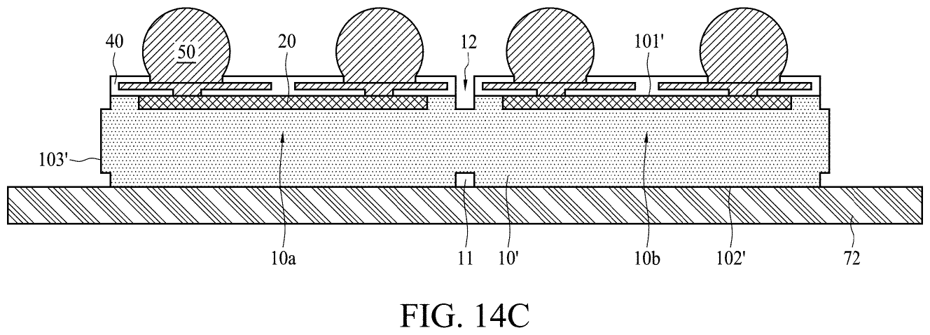

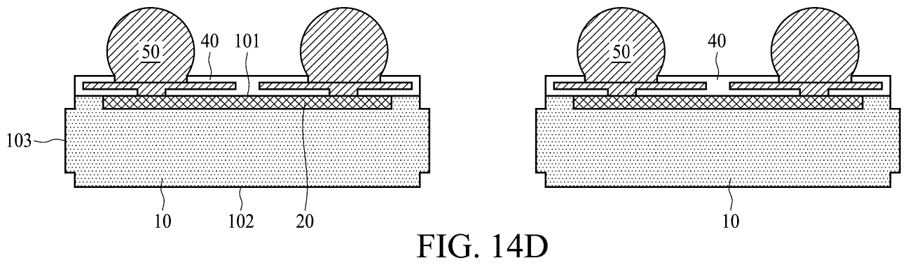

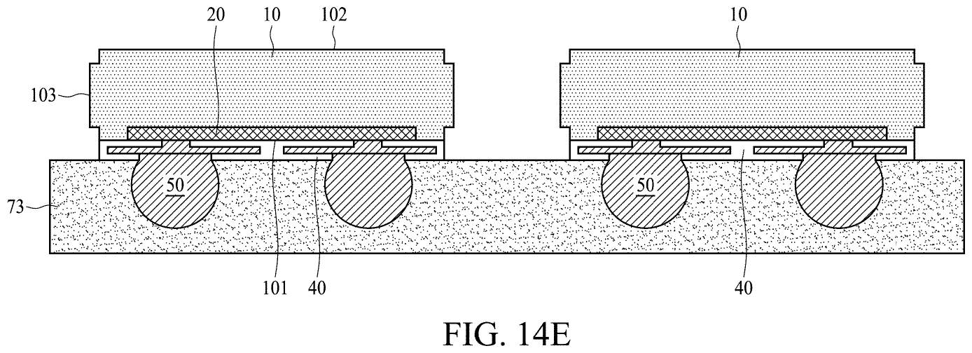

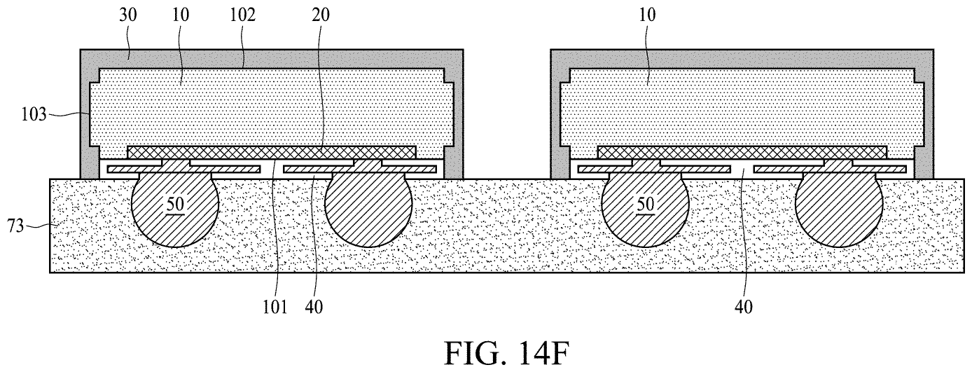

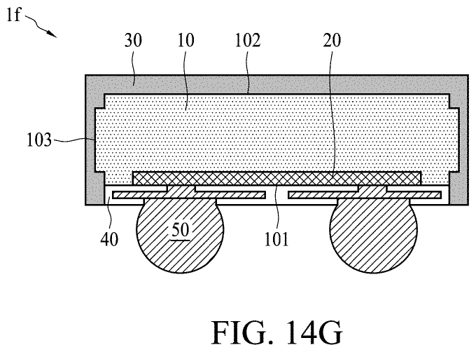

FIG. 14A, FIG. 14B, FIG. 14C, FIG. 14D, FIG. 14E, FIG. 14F. FIG. 14G and FIG. 14H illustrate various stages of a method for manufacturing a semiconductor package structure if in accordance with some embodiments of the present disclosure.

Referring to FIG. 14A, a substrate 10′ is provided. The substrate 10′ may include a portion 10a and a portion 10b. Each of the portion 10a and the portion 10b may correspond to the semiconductor die 10 after the substrate 10′ is singulated. Multiple active layers 20, passivation layer(s) 40 and/or terminals 50 may be disposed or formed on each of the portion 10a and the portion 10b. The substrate 10′ may include a surface 101′, a surface 102′ and a surface 103′. The surface 101′ may be a surface on which the active layer 20 is disposed. The surface 102′ may be a backside surface. The surface 103′ may be a side surface. In some embodiments, the surface 102′ may be thinned such that the substrate 10′ may have a thickness below 300 μm.

Referring to FIG. 14B, the terminal 50 may be attached to a carrier 71 through an adhesive 80. In some embodiments, a portion of the surface 102′ is removed or recessed. In some embodiments, the portion corresponding to the scribe line (not shown) between the portion 10a and the portion 10b is removed or recessed to form a notch 11. In addition, the peripheral region of surface 102′ is removed. In some embodiments, the substrate 10′ may be removed with a step cut. In some embodiments, the substrate 10′ may be removed with a bevel cut such that the substrate 10′ may have tapered portion(s).

Referring to FIG. 14C, after the portion of the surface 102′ of the substrate 10′ is removed or recessed, the carrier 71 is removed, and the surface 101′ may be attached to a carrier 72. In some embodiments, a portion of the surface 101′ is removed or recessed. In some embodiments, the portion corresponding to the scribe line (not shown) between the portion 10a and the portion 10b is removed or recessed to form a notch 12. In addition, the peripheral region of surface 101′ is removed. In some embodiments, the notch 11 is aligned to the notch 12.

Referring to FIG. 14D, the substrate 10′ is singulated to form a plurality of semiconductor die 10 separated from each other. In some embodiments, the substrate 10′ is cut through the notch 11 and/or 12.

Referring to FIG. 14E, the semiconductor die 10 may be attached to a carrier 73 such as a tape.

Referring to FIG. 14F, the light absorbing layer 30 is formed on the semiconductor die 10 to cover the surface 102 and the surface 103 of the semiconductor die 10. In some embodiments, a light absorbing material is prepared. The light absorbing material may have a viscosity ranging from about 2 Cp to about 11 Cp. The light absorbing material may be formed on the semiconductor die 10 through a spray coating process. After the light absorbing material is coated on the semiconductor die 10, the light absorbing material may be thermally cured by e.g., a bake process to form the light absorbing layer 30.

Referring to FIG. 14G, the carrier 73 is removed, and the semiconductor package structure if is produced.

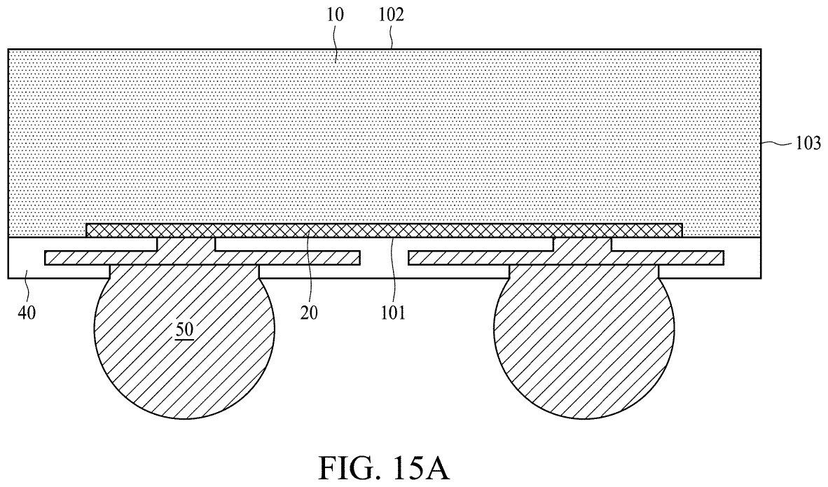

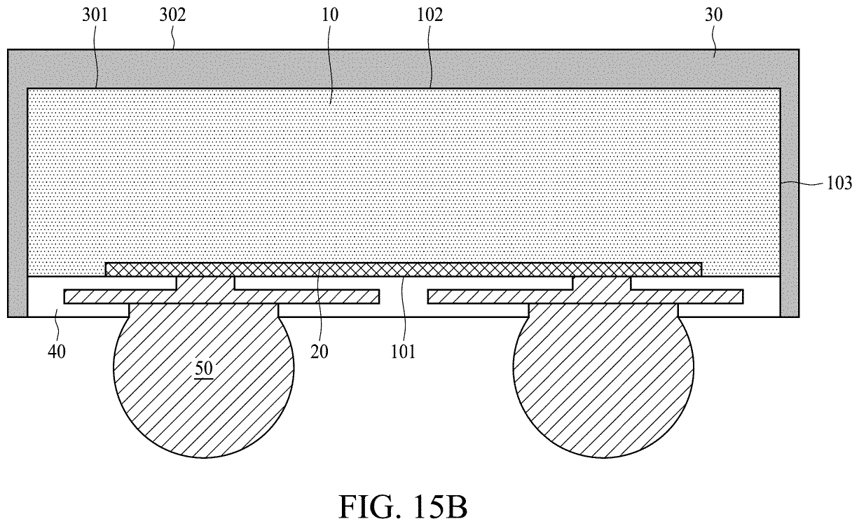

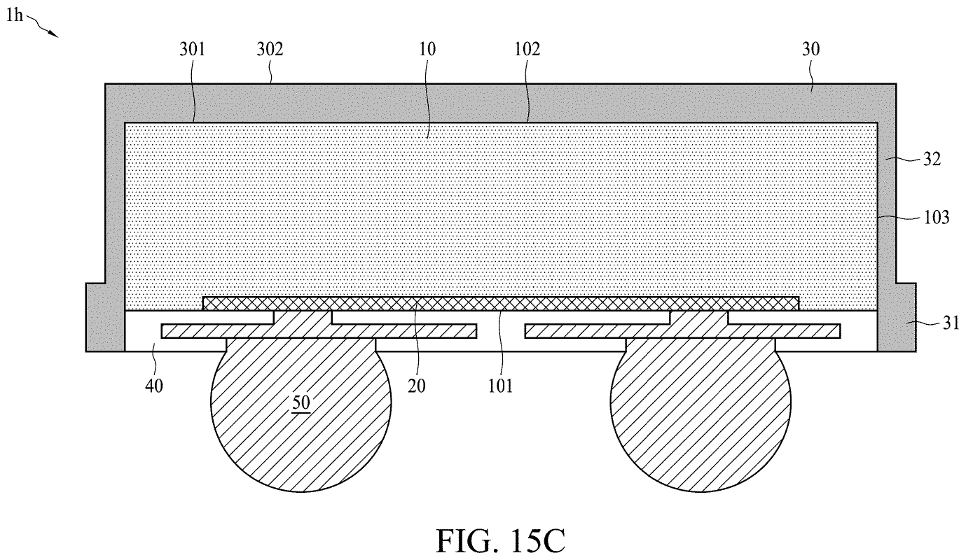

FIG. 15A, FIG. 15B and FIG. 15C illustrate various stages of a method for manufacturing a semiconductor package structure 1h in accordance with some embodiments of the present disclosure.

FIG. 15A depict a stage subsequent to that depicted in FIG. 14A. Referring to FIG. 15A, the semiconductor die 10 is provided without formation of step profiles or tapered portions. More specifically, the substrate 10′ is singulated without formation of recessed portion or notch. In some embodiments, the semiconductor die 10 may be attached to and supported by a carrier such as a tape.

Referring to FIG. 15B, a first coating process is performed to coat a light absorbing material on the surface 102 and the surface 103 of the semiconductor die 10, and a first curing process such as a bake process may be performed to solidify the light absorbing material. In some embodiments, the edge of the carrier may be slightly warped, and the light absorbing material may insert into the space between the passivation layer 40 and the carrier. As a result, the semiconductor package structure 1a′ is produced.

Referring to FIG. 15C, a second coating process is performed to locally coat light absorbing material on the semiconductor die 10, and a second curing process such as a bake process may be performed to solidify the light absorbing material. As a result, the light absorbing layer 30 may have a thicker portion abutting the surface 101 and a thinner portion. As a result, the semiconductor package structure 1h is produced.

According to the embodiments of the disclosure, the semiconductor package structure includes a light absorbing layer covering the backside surface and the side surface of the semiconductor die. The light absorbing layer can prevent from light being incident to the semiconductor die. According to the embodiments of the disclosure, the light absorbing layer may include a thicker portion disposed at the corner of the active surface and the side surface, which can further reduce light being incident to the active layer of the semiconductor die. According to the embodiments of the disclosure, the light absorbing layer may include a thicker portion disposed at the corner of the backside surface and the side surface, which can compensate the thickness due to sagging phenomenon. The light absorbing layer can enhance the reliability of the semiconductor package structure. The light absorbing layer can prevent from delamination of the passivation layer and the semiconductor die.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A semiconductor package structure, comprising:
a semiconductor die having a first surface, a second surface and a third surface, wherein an active layer of the semiconductor die is adjacent to first surface, the second surface is opposite to the first surface, and the third surface extends from the first surface to the second surface;
a light absorbing layer covering the second surface and the third surface of the semiconductor die,
wherein the semiconductor die has a thickness defined from the first surface to the second surface, and the thickness of the semiconductor die is less than or equal to about 300 micrometers (μm).

2. The semiconductor package structure of claim 1, wherein the light absorbing layer has a thickness ranging from about 1.5 μm to about 30 μm.

3. The semiconductor package structure of claim 1, further comprising a passivation layer covering the first surface of the semiconductor die.

4. The semiconductor package structure of claim 3, wherein the passivation layer partially covers the first surface of the semiconductor die, and the light absorbing layer further covers a portion of the first surface of the semiconductor die.

5. The semiconductor package structure of claim 3, wherein the passivation layer fully covers the first surface of the semiconductor die, and the light absorbing layer further covers a portion of the passivation layer.

6. The semiconductor package structure of claim 1, wherein the light absorbing layer includes a first portion having a first thickness, and a second portion having a second thickness less than the first thickness.

7. The semiconductor package structure of claim 6, wherein the first portion of the light absorbing layer abuts the first surface and surrounds the active layer.

8. The semiconductor package structure of claim 7, wherein the first portion of the light absorbing layer includes an elevation higher than an elevation of the active layer.

9. The semiconductor package structure of claim 6, wherein the first portion of the light absorbing layer is disposed on the third surface and abuts the second surface.

10. The semiconductor package structure of claim 6, wherein the first portion and the second portion of the light absorbing layer form a step profile.

11. The semiconductor package structure of claim 10, wherein the light absorbing layer includes an inner surface facing the semiconductor die and an outer surface opposite to the inner surface, and the inner surface or the outer surface of the first portion and the inner surface or the outer surface of the second portion form the step profile.

12. The semiconductor package structure of claim 6, wherein the first portion of the light absorbing layer includes a tapered portion.

13. The semiconductor package structure of claim 12, wherein the light absorbing layer includes an inner surface facing the semiconductor die and an outer surface opposite to the inner surface, and the inner surface of the tapered portion of the light absorbing layer is tapered with respect to the outer surface of the tapered portion.

14. The semiconductor package structure of claim 12, wherein the tapered portion of the light absorbing layer tapers along a direction from the first surface toward the second surface or the tapered portion of the light absorbing layer tapers along the direction from the second surface toward the first surface.

15. The semiconductor package structure of claim 1, wherein the light absorbing layer has a curved surface at a corner of the second surface and the third surface of the semiconductor die.

16. The semiconductor package structure of claim 1, further comprising:
a shielding layer disposed between the semiconductor die and the light absorbing layer.

17. A method of manufacturing a semiconductor package structure, comprising:
providing a substrate with a first surface and a second surface opposite to the first surface;
recessing at least one of the first surface and the second surface of the substrate;
singulating the substrate to form a first semiconductor die and a second semiconductor die; and
forming light absorbing layers on each of the first semiconductor die and the second semiconductor die.

18. The method of claim 17, wherein recessing at least one of the first surface and the second surface of the substrate comprises forming a plurality of first notches on the first surface of the substrate, and singulating the substrate to form the first semiconductor die and the second semiconductor die comprises cutting the substrate through the first notches such that each of the first semiconductor die and the second semiconductor die has a first step profile or a first tapered profile.

19. The method of claim 17, wherein recessing at least one of the first surface and the second surface of the substrate comprises forming a plurality of second notches on the second surface of the substrate, and singulating the substrate to form the first semiconductor die and the second semiconductor die comprises cutting the substrate through the second notches such that each of the first semiconductor die and the second semiconductor die has a second step profile or a second tapered profile.

20. The method of claim 17, wherein forming the light absorbing layers on each of the first semiconductor die and the second semiconductor die comprises spray coating a light absorbing material on each of the first semiconductor die and the second semiconductor, and a viscosity of the light absorbing material ranges from about 2 Cp to about 11 Cp.
